(19) United States
(12) Patent Application Publication
(10) Pub. No.: US 2014/0093723 A1
(43) Pub. Date: Apr. 3, 2014

(54) SUBSTRATE, METHOD FOR PRODUCING SAME, HEAT-RELEASING SUBSTRATE, AND HEAT-RELEASING MODULE

(71) Applicants: Masaki Takeuchi, Chikusei-shi (JP); Yoshitsugu Matsuura, Chikusei-shi (JP); Kazuhito Obata, Chikusei-shi (JP)

(72) Inventors: Masaki Takeuchi, Chikusei-shi (JP); Yoshitsugu Matsuura, Chikusei-shi (JP); Kazuhito Obata, Chikusei-shi (JP)

(21) Appl. No.: 14/122,655

(22) PCT Filed: May 23, 2012
(86) PCT No.: PCT/JP2012/063227

§ 371 Date: Nov. 26, 2013

(30) Foreign Application Priority Data
May 27, 2011 (JP) 2011-119555

(51) Int. Cl. H05K 1/03; F28F 21/08

(52) U.S. Cl. CPC H05K 1/036; F28F 21/08
USPC 428/336; 165/185; 427/207.1

(57) ABSTRACT

The invention provides a substrate, including: a metal foil; a polyimide resin layer having an average thickness of from 3 μm to 25 μm, the polyimide resin layer being disposed on a surface of the metal foil having an arithmetic average roughness (Ra) of 0.3 μm or less and a maximum roughness (Rmax) of 2.0 μm or less; and an adhesive layer having an average thickness of from 5 μm to 25 μm, the adhesive layer being disposed on the polyimide resin layer.

### TECHNICAL FIELD

The invention provides a substrate and a method for producing the same, a heat-releasing substrate, and a heat-releasing module.

### BACKGROUND

Conventionally, a metal-core substrate, having a structure in which an insulating material layer is formed on a metal plate and a wiring pattern is formed on the insulating material layer, has been widely used as a heat-releasing substrate for mounting electronic components thereon.

A wiring pattern is generally formed by laminating a copper foil on an insulating material layer, and ceramic chip elements, silicon semiconductors, terminals and the like are mounted on the wiring pattern with a solder.

As the insulating material layer, for example, Japanese Patent No. 3255315 proposes a thermoplastic polyimide or a polyphenylene ether (PPE) to which an inorganic filler is added. However, since common resins such as thermoplastic polyimide or PPE have a low heat conductivity, it may be difficult to use these resins for a heat-releasing substrate for electronic devices of recent years, such as PDPs (plasma display panels) or LEDs (light-emitting diodes) that are required to be highly heat-releasing. Therefore, increasing heat conductivity of an insulating material layer has been an issue for study and, for example, Japanese Patent Application Laid-Open (JP-A) Nos. H11-323162 and 2008-106126 propose a use of a crystalline resin as a means for increasing the heat conductivity of a resin. Further, for example, JP-A No. 2007-150224 studies a use of a highly heat-conductive filler.

### SUMMARY OF THE INVENTION

### Problem to be Solved

However, the crystalline resin and the highly heat-conductive filler as described in JP-A Nos. H11-323162 and 2008-1061226 tend to cause a decrease in insulating properties and an adhesive layer having a thickness of approximately 100 μm is required. Therefore, there is a limit in reducing the thickness of the substrate.

The invention aims to solve the problem set forth above by providing a substrate that has a reduced thickness and exhibits excellent reliability and stable heat-releasing properties.

### Means for Solving the Problem

The inventors have made intensive studies and, as a result, found a suitable substrate for addressing the problem, which is a substrate that includes a metal foil, which has an arithmetic average roughness (Ra) of 0.3 μm or less and a maximum roughness (Rmax) of 2.0 μm or less at the side to be in contact with a polyimide resin layer, a polyimide resin layer that is disposed on the metal foil and has an average thickness of from 2 μm to 25 μm, and an adhesive layer including polyamideimide that is disposed on the polyimide resin layer and has an average thickness of from 5 μm to 25 μm.

The invention includes the following embodiments.

<1> A substrate, comprising: a metal foil; a polyimide resin layer having an average thickness of from 3 μm to 25 μm, the polyimide resin layer being disposed on a surface of the metal foil having an arithmetic average roughness (Ra) of 0.3 μm or less and a maximum roughness (Rmax) of 2.0 μm or less; and an adhesive layer having an average thickness of from 5 μm to 25 μm, the adhesive layer being disposed on the polyimide resin layer.

<2> The substrate according to <1>, further comprising a metal plate that is disposed on the adhesive layer.

<3> The substrate according to <1> or <2>, wherein an adhesion between each of the layers after a thermal treatment at 150° C. for 500 hours is 0.5 kN/m or more, respectively.

<4> The substrate according to any one of <1> to <3>, wherein a breakdown voltage of the polyimide resin layer and the adhesive layer as a whole is 3 kV or more.

<5> The substrate according to any one of <1> to <4>, wherein an elastic modulus at normal temperature of an adhesive resin after curing, the adhesive resin being included in the adhesive layer, is from 200 MPa to 1,000 MPa.

<6> The substrate according to any one of <1> to <5>, wherein the polyimide resin layer comprises a polyimide resin that is obtained from an acid anhydride that comprises a biphenyl tetracarboxylic acid anhydride and a diamine that comprises a diaminodiphenyl ether and a phenylene diamine.

<7> The substrate according to any one of <1> to <6>, wherein the adhesive layer comprises a siloxane-modified polyamideimide resin and an epoxy resin.

<8> The substrate according to any one of <1> to <7>, wherein: a total content of a resin in a solid content of the adhesive layer is 100% by mass or less; and contents in the solid content of a siloxane-modified polyamideimide resin, an epoxy resin having two or more epoxy groups in a molecule that is compatible with the siloxane-modified polyamideimide resin, and a polyfunctional resin having three or more functional groups that are reactive with the epoxy group in a molecule, which are included in the resin, are from 30% by mass to 60% by mass, 10% by mass or more and 10% by mass or more, respectively.

<9> A heat-releasing substrate that is the substrate according to any one of <1> to <8>, wherein the metal foil is circuit-processed.

<10> A heat-releasing module, comprising the heat-releasing substrate according to <9> and an element disposed on the heat-releasing substrate.

<11> A method of producing a substrate, the method comprising: a process of preparing a polyimide precursor that is a reactant of an acid anhydride that comprises a biphenyl tetracarboxylic acid anhydride and a diamine that comprises a diaminodiphenyl ether and a phenylene diamine; a process of applying the polyimide precursor to a surface of a metal foil having an arithmetic average roughness (Ra) of 0.3 μm or less and a maximum roughness (Rmax) of 2.0 μm or less; a process of forming a polyimide resin layer by obtaining a polyimide resin from the polyimide precursor by causing cyclodehydration of the polyimide precursor in an atmosphere of a mixture of nitrogen gas and hydrogen gas; and a process of providing an adhesive layer on the polyimide resin layer.

<12> The method of producing a substrate according to <11>, wherein the polyimide precursor is a reactant obtained by reaction of a diamine that comprises from 0.15 mol to 0.25 mol of the diaminodiphenyl ether and from 0.75 mol to 0.85 mol of the phenylene diamine with 1 mol of the biphenyl tetracarboxylic acid anhydride.

### Effect of the Invention

According to the invention, it is possible to provide a substrate that has a reduced thickness and exhibits excellent reliability and stable heat-releasing properties.

### BRIEF EXPLANATION OF THE DRAWINGS

FIG. 1 is a schematic sectional view of an example of a heat-releasing module according to the present embodiment.

FIG. 2 is a schematic sectional view of an example of how to use a heat-releasing module according to the present embodiment.

### EMBODIMENTS FOR IMPLEMENTING THE INVENTION

The invention relates to a substrate that includes: a metal foil; a polyimide resin layer having an average thickness of from 3 μm to 25 μm, the polyimide resin layer being disposed on a surface of the metal foil having an arithmetic average roughness (Ra) of 0.3 μm or less and a maximum roughness (Rmax) of 2.0 μm or less; and an adhesive layer having an average thickness of from 5 μm to 25 μm, the adhesive layer being disposed on the polyimide resin layer. Generally, as the thickness of the polyimide layer is decreased when forming the same on the metal foil in order to reduce the heat resistance, the breakdown voltage tends to decrease. The inventors have found that a decrease in the breakdown voltage can be suppressed even if the thickness of the polyimide layer is reduced, by regulating the roughness at a surface of the metal foil to be within a specific range. Namely, the invention provides a substrate that achieves both an improvement in the breakdown voltage and a reduction in the heat resistance.

In the present specification, the term “process” refers not only an independent process but also a process that cannot be clearly distinguished from another process, as long as an intended object is achieved. The numerical value indicated as A to B refers to a range that includes A and B as a minimum value and maximum value, respectively. When there are plural substances that correspond to each component, the amount of the component in the composition refers to the total amount of the substances that exist in the composition, unless otherwise specified.

<Substrate>

The substrate of the invention includes: a metal foil; a polyimide resin layer having an average thickness of from 3 μm to 25 μm, the polyimide resin layer being disposed on a surface of the metal foil having an arithmetic average roughness (Ra) of 0.3 μm or less and a maximum roughness (Rmax) of 2.0 μm or less; and an adhesive layer having an average thickness of from 5 μm to 25 μm, the adhesive layer being disposed on the polyimide resin layer.

By having the structure as described above, the substrate exhibits a high breakdown voltage and a high reflow resistance during mounting elements thereon. The substrate also exhibits an excellent reliability, i.e., suppressed occurrence of failures such as interlayer separation even after being exposed to a high temperature for a long time, and stable heat-releasing properties, even with a reduced thickness. The substrate of the invention is suitably used as, for example, a heat-releasing substrate for mounting LEDs thereon.

(Metal Foil)

The metal foil is not particularly limited as long as it has at least one surface with an arithmetic average roughness (Ra) of 0.3 μm or less and a maximum roughness (Rmax) of 2.0 μm or less. The material of the metal foil is not particularly limited, and examples of the material include gold, copper and aluminum. In general, a copper foil is used.

In addition, the metal foil may be a composite foil having a three-layer structure in which an intermediate layer made of nickel, nickel-phosphorous, nickel-tin alloy, nickel-iron alloy, lead, lead-tin alloy, or the like is sandwiched with a copper layer having a thickness of from 0.5 μm to 15 μm and a copper layer having a thickness of from 10 μm to 300 μm, or a composite foil having a two-layer structure formed of a composite of aluminum and a copper foil.

The surface of the metal foil having an arithmetic average roughness (Ra) of 0.3 μm or less preferably has an arithmetic average roughness (Ra) of from 0.1 μm to 0.3 μm, more preferably from 0.2 μm to 0.3 μm, from the viewpoint of adhesion with respect to the polyimide resin layer.

In addition, the surface of the metal foil having a maximum roughness (Rmax) of 2.0 μm or less preferably has a maximum roughness (Rmax) of from 1.0 μm to 2.0 μM, more preferably from 1.5 μm to 2.0 μm, from the viewpoint of adhesion with respect to the polyimide resin layer after a thermal treatment.

When the surface roughness of the metal foil is large, i.e., an arithmetic average roughness (Ra) of greater than 0.3 μm or a maximum roughness (Rmax) of greater than 2.0 μm, the breakdown voltage may decrease. The reason for this is thought to be, for example, that electric fields concentrate at uneven portions at the surface of the metal foil. In addition, when the surface of the metal foil on which the polyimide resin layer is to be disposed has a large surface roughness as described above, the thickness of the polyimide resin layer tends to become uneven and the in-plane heat conductivity tends to vary at different portions.

The arithmetic average roughness and the maximum roughness at the surface of the metal foil are measured with a stylus profilometer at room temperature and a measurement force of 0.7 mN.

As a method for adjusting the arithmetic average roughness and the maximum roughness at the surface of the metal foil to be within the predetermined ranges, a common method for regulating the surface roughness of a metal foil can be used without particular limitation.

It is also possible to use a metal foil selected from commercial items having an arithmetic average roughness and a maximum roughness within the predetermined ranges, such as an electrolytic copper foil manufactured by Fukuda Metal Foil & Powder Co., Ltd., and an electrolytic copper foil manufactured by Nippon Denkai, Ltd.

The ratio of the maximum roughness (Rmax) to the arithmetic average roughness (Ra) at the surface of the metal foil (maximum roughness/arithmetic average roughness) is not particularly limited. For example, from the viewpoint of an adhesion between a copper foil and polyimide, the ratio is preferably from 5 to 15, more preferably from 7 to 12.

The average thickness of the metal foil is not particularly limited. In particular, the average thickness of the metal foil is preferably 6 μm or more, more preferably from 6 μm to 40 μm, still more preferably from 9 μm to 35 μm. When a metal foil having an average thickness of 6 μm or more is used, production efficiency can be improved.

The average thickness of the metal foil is given as an arithmetic average value obtained from the thicknesses measured at randomly selected 10 points with a stylus profilometer.

(Polyimide Resin Layer)

In the substrate of the invention, a polyimide resin layer is provided on one surface of the metal foil as mentioned above having an arithmetic average roughness (Ra) of 0.3 μm or less and a maximum roughness (Rmax) of 2 μm or less. The polyimide resin layer has an average thickness of from 3 μm to 25 μm. The average thickness of the polyimide resin layer is preferably from 3 μm to 15 μm, more preferably from 5 μm to 15 μm. When the average thickness of the polyimide resin layer is less than 3 μm, a sufficient breakdown voltage (preferably, 1 kV or more) may not be achieved. When the average thickness of the polyimide resin layer exceeds 25 μm, a sufficient heat conductivity may not be achieved.

The average thickness of the resin layer is given as an arithmetic average value obtained from the thicknesses measured at randomly selected 10 points with a stylus profilometer.

The ratio of the average thickness of the polyimide resin layer to the arithmetic average roughness (Ra) at the surface of the metal foil (polyimide resin layer thickness/arithmetic average roughness) is not particularly limited. For example, from the viewpoint of adhesion, the ratio is preferably 10 or more, more preferably from 15 to 125.

The ratio of the ratio of the average thickness of the polyimide resin layer (polyimide resin layer thickness/arithmetic average roughness) to the maximum roughness (Rmax) of the metal foil surface (polyimide resin layer thickness/maximum roughness) is not particularly limited. For example, from the viewpoint of heat conductivity and a breakdown voltage, the ratio is preferably from 1 to 20, more preferably from 1.5 to 15.

In addition, an adhesion between the polyimide resin layer and the metal foil is preferably 0.5 kN/m or more, more preferably 0.8 kN/m or more, after performing a thermal treatment at 150° C. for 500 hours. When the adhesion after the thermal treatment is within the above range, interlayer separation of a substrate can be suppressed and a substrate having an excellent reliability and excellent heat releasing properties can be obtained. Furthermore, the adhesion between the polyimide resin layer and the metal foil is preferably 0.7 kN/m or more, more preferably 0.9 kN/m or more, before performing a thermal treatment at 150° C. for 500 hours. When the adhesion before the thermal treatment is within the range set forth above, repairability in a case in which elements such as LEDs are attached to a circuit by mistake is improved. The adhesion is measured with a tensile tester (for example, RTM 500, manufactured by Orientec Co., Ltd.) at a peel angle of 90 degrees and a rate of 50 mm/min.

Examples of the method for adjusting the adhesion between the polyimide resin layer and the metal foil after performing the thermal treatment include a method of forming a polyimide resin layer such that the polyimide resin includes a specific polyimide resin as described below, and a method of increasing the maximum roughness of the metal foil as much as possible within a range that is tolerable in terms of a breakdown voltage.

The breakdown voltage of the polyimide resin layer and the adhesive layer as a whole is preferably 3 kV or more, more preferably 4 kV or more. When the breakdown voltage is 3 kV or more, reliability of the substrate is further improved.

In the present specification, the breakdown voltage of the polyimide resin layer is a value measured in a layer thickness direction of the entire polyimide resin layer constituting the substrate of the present invention. The breakdown voltage is measured with a withstand voltage tester (TOS 8700, manufactured by Kikusui Electronics Corporation) at a condition of 2 mA.

Examples of the method for adjusting the breakdown voltage of the polyimide resin layer after the thermal treatment to be within the range set forth above include a method of increasing the thickness of the polyimide resin layer within a range of 25 μm or less, a method of forming a polyimide resin layer by including a specific polyimide resin as described below, and a method of minimizing the surface roughness (roughening) of the metal foil.

The polyimide resin that constitutes the polyimide resin layer is not particularly limited. For example, the polyimide resin may be selected from polyimide resins that are commonly used for forming a flexible printed circuit board. Specifically, the polyimide resin may be selected from polyimide resins described in JP-A No. S60-210629, JP-A No. S64-16832, JP-A No. H01-131241, JP-A No. S59-164328, JP-A No. S61-111359 and the like.

The polyimide resin that constitutes the polyimide resin layer may be a single kind of polyimide resin or a combination of two or more kinds of polyimide resins.

The polyimide resin is preferably a product obtained from an acid anhydride including a biphenyl tetracarboxylic acid anhydride and a diamine including at least one of a diaminodiphenyl ether and a phenylene diamine; more preferably a product obtained from an acid anhydride including a biphenyl tetracarboxylic acid anhydride and a diamine including a diaminodiphenyl ether and a phenylene diamine; still more preferably a product obtained by reaction of an acid anhydride including 1 mol of a biphenyl tetracarboxylic acid anhydride with a diamine including from 0.15 mol to 0.25 mol of a diaminodiphenyl ether and from 0.75 mol to 0.85 mol of a phenylene diamine; particularly preferably a product obtained by reaction of an acid anhydride including 1 mol of a biphenyl tetracarboxylic acid anhydride with a diamine including from 0.15 mol to 0.25 mol of a diaminodiphenyl ether and from 0.75 mol to 0.85 mol of a phenylene diamine, wherein the total amount of the diaminodiphenyl ether and the phenylene diamine is from 0.9 mol to 1.1 mol.

By using a polyimide resin having a configuration as specified above (hereinafter, also referred to as a “specific polyimide resin”), adhesion between the polyimide resin layer and the metal foil is further improved. In addition, a breakdown voltage is further improved.

The polyimide resin layer is formed by including at least one polyimide resin, preferably a specific polyimide resin, and other components as necessary. Examples of the other components include a solvent and an inorganic filler.

Examples of the solvent include an amide solvent such as N-methyl-2-pyrrolidone and N,N-dimethylacetoamide.

The content of the polyimide resin in the polyimide resin layer is preferably 40% by volume or more in a solid content of the polyimide resin layer. From the viewpoint of maintaining the strength of the polyimide, the content thereof is more preferably 60% by volume or more, still more preferably 70% by volume or more.

In the present specification, the solid content refers to the balance from which volatile components are excluded.

The method for providing the polyimide resin layer on the metal foil is not particularly limited, as long as it is possible to form a polyimide resin layer having an average thickness of from 3 μm to 25 μm. For example, the polyimide resin layer can be formed on the metal foil by a method including a process of obtaining a polyimide precursor by reacting an acid anhydride with a diamine, a process of applying the polyimide precursor (preferably, a polyimide precursor varnish) onto the metal foil to form a polyimide precursor layer on the metal foil, and a process of forming a polyimide resin layer by obtaining a polyimide resin from the polyimide precursor by causing cyclodehydration of the polyimide precursor through a thermal treatment.

The polyimide precursor varnish includes at least a polyimide precursor and a solvent.

The polyimide precursor is obtained by mixing an acid anhydride and a diamine, and allowing the same to react. The mixing ratio of the acid anhydride and the diamine is not particularly limited, but the ratio of the acid anhydride to the diamine (acid anhydride/diamine) is preferably from 0.9 to 1.1, more preferably from 0.95 to 1.05, on an equivalent basis.

When the ratio of the acid anhydride to the diamine is within the range as described above, the molecular weight of the polyimide resin to be formed can be suitably controlled, whereby the strength of the polyimide resin layer is improved.

In the present specification, when the acid anhydride or the diamine is composed of two or more kinds of acid anhydrides or diamines, the total amount of the acid anhydrides and the total amount of the diamines preferably satisfy the above range, respectively.

It is also possible to use a commercially available polyimide precursor, instead of performing a process of obtaining a polyimide precursor.

The method for applying the polyimide precursor on the metal foil in the process of forming the polyimide precursor layer is not particularly limited, as long as the polyimide precursor layer can be formed so as to have a predetermined thickness. The method may be selected from commonly used liquid application methods.

For example, a known application method may be used. Specific examples of the application method include comma coating, die coating, lip coating and gravure coating. As an application method for forming a polyimide precursor layer into a predetermined thickness, a comma coating method in which a medium to be coated is passed through a gap, a die coating method in which a polyimide precursor varnish is applied while adjusting the flow rate from a nozzle, and the like are preferred.

When the polyimide precursor layer is formed by application of a polyimide precursor varnish, it is preferable to provide a drying process of removing at least a part of a solvent included in the polyimide resin varnish after the application.

In order to remove the solvent in the drying process, a common solvent removal method can be used without particular limitation. Examples of the solvent removal method include a thermal treatment performed at from 90° C. to 130° C. for from 5 minutes to 30 minutes.

The residual solvent rate in the polyimide precursor layer after performing the drying process is not particularly limited, but is preferably from 30% by mass to 45% by mass.

The conditions for cyclodehydration in the process of obtaining the polyimide resin layer are not particularly limited, as long as the polyimide precursor can be converted to a polyimide resin by cyclodehydration. Examples of the conditions include a method of performing a thermal treatment at from 350° C. to 550° C. in a non-oxidizing atmosphere that includes substantially no oxygen (preferably, the oxygen content is 0.5% by volume or less). Specifically, from the viewpoint of adhesion and regulating a thermal expansion coefficient, the conditions are preferably a method of performing a thermal treatment at from 380° C. to 550° C. in a non-oxidizing mixed gas atmosphere including nitrogen gas and hydrogen gas, more preferably a method of performing a thermal treatment at from 400° C. to 550° C. in a mixed gas atmosphere including nitrogen and hydrogen, wherein the hydrogen content is from 0.1% by volume to 4% by volume.

By performing cyclodehydration at a temperature of 350° C. or more, a sufficient cyclodehydration rate can be achieved, whereby a breakdown voltage is further improved. By performing cyclodehydration at a temperature of 550° C. or less, thermal decomposition of the polyimide precursor and the polyimide resin can be suppressed.

By performing cyclodehydration in a non-oxidizing mixed gas atmosphere including nitrogen and hydrogen, oxidative decomposition of the polyimide precursor and the polyimide resin can be suppressed, whereby a breakdown voltage is further improved.

When the hydrogen content in the nonoxidizing mixed gas atmosphere is 0.1% by volume or more, the effect of suppressing oxidative decomposition is further improved. When the hydrogen content is 4% by volume or less, safety during the production is improved.

On the polyimide resin layer, an adhesive layer is provided. The surface of the polyimide resin layer that contacts the adhesive layer may be subjected to various surface treatments as needed. By performing a surface treatment, wettability of the surface of the polyimide resin layer with respect to an adhesive resin layer, in particular, wettability of an adhesive varnish in case in which an adhesive resin layer is formed by applying the adhesive varnish onto the polyimide resin layer. By performing a surface treatment, occurrence of repelling, unevenness or the like can be suppressed, thereby further improving and stabilizing the adhesion.

The method for a thermal treatment may be selected from common methods in accordance with purposes. Examples of the methods include UV radiation, corona discharge treatment, buffing, sandblasting, dry etching and wet etching. Among them, dry etching performed by an oxygen plasma treatment is preferred in terms of ease of performing a treatment in a continuous manner, stability in an effect of the treatment, and greatness of the effect.

By performing dry etching by an oxygen plasma treatment, the adhesion between the polyimide resin layer and the adhesive layer can be improved more effectively, and a substrate that is more reliable and more stable in heat conductivity can be obtained. In addition, the thickness of the adhesive layer can be further reduced. The reason for this is thought to be, for example, that the wettability between the polyimide resin layer and the adhesive varnish is improved more effectively by performing the oxygen plasma treatment.

(Adhesive Layer)

In the substrate of the invention, the adhesive layer is provided on the polyimide resin layer. The adhesive layer has an average thickness of from 5 μm to 25 μm, preferably from 5 μm to 15 μm, more preferably from 5 μm to 10 μm, from the viewpoint of heat conductivity, adhesion and a breakdown voltage.

When the average thickness of the adhesive layer is less than 5 μm, for example, the thickness of the adhesive layer may become equal to or less than the maximum surface roughness at a surface to be attached to a heat-releasing metal plate, whereby a breakdown voltage tends to become low because the polyimide resin layer may be damaged in a process of attaching to the heat-releasing metal plate. When the average thickness of the adhesive layer exceeds 25 μm, heat conductivity tends to decrease.

The average thickness of the adhesive layer is given as an arithmetic average value obtained from the thicknesses measured at randomly selected 10 points with a stylus profilometer.

The ratio of the average thickness of the adhesive layer to the average thickness of the polyimide resin layer (adhesive layer/polyimide resin layer) is not particularly limited. For example, from the viewpoint of heat conductivity and a breakdown voltage, the ratio is preferably from 0.3 to 5, more preferably from 0.3 to 2.5.

The sum of the average thickness of the polyimide resin layer and the average thickness of the adhesive layer (hereinafter, also referred to as a “resin layer thickness”) is not particularly limited. For example, from the viewpoint of heat conductivity and a breakdown voltage, the resin layer thickness is preferably from 10 μm to 35 μm, more preferably from 10 μm to 25 μm.

The adhesion between the polyimide resin layer and the adhesive layer, and the adhesion between the adhesive layer and the heat-releasing metal plate that is provided as needed, are preferably 0.5 kN/m or more, more preferably 0.8 kN/m or more, respectively, after performing a thermal treatment at 150° C. for 500 hours. When the adhesion is within the range as described above, reliability of the substrate is further improved. The adhesion between the polyimide resin layer and the adhesive layer, and the adhesion between the adhesive layer and the heat-releasing metal plate that is provided as needed, are preferably 0.7 kN/m or more, more preferably 0.8 kN/m or more, before performing a thermal treatment at 150° C. for 500 hours. When the adhesion before the thermal treatment is within the range as described above, it is possible to suppress degradation in yield due to swelling that may occur during solder bonding reflow for mounting elements such as LEDs.

Examples of the method for adjusting the adhesion of the adhesive layer to be within the above range include a method of performing dry etching of the polyimide resin layer by an oxygen plasma treatment, a method of forming an adhesive layer including a specific resin as described later, and a method of applying a primer onto a surface of the polyimide resin layer.

The elastic modulus at room temperature (25° C.) of an adhesive resin after curing, which is included in the adhesive layer, is preferably from 200 MPa to 1,000 MPa, more preferably from 300 MPa to 800 MPa. When the elastic modulus is 1,000 MPa or less, a stress generated by thermal expansion can be eased and occurrence of cracking at an interface with the adhesive layer can be suppressed. When the elastic modulus is 200 MPa or more, occurrence of sinking of elements such as LEDs during mounting the same on the substrate can be suppressed.

In the specification, the elastic modulus after curing refers to an elastic modulus of an adhesive resin included in the adhesive layer at a time when the adhesive resin is completely cured. The conditions for the curing depend on the kinds of the resin and the curing agent, and the like. In a case in which an epoxy resin and a curing agent therefor are used, for example, the conditions may be a thermal treatment performed at 185° C. for 90 minutes.

The elastic modulus is measured with a tensile tester (for example, RTM 500, manufactured by Orientec Co., Ltd.) at a peel angle of 90 degrees and at a rate of 50 mm/min.

Examples of a method for adjusting the elastic modulus of the adhesive resin after curing include a method of selecting an adhesive resin and a curing agent from known compounds. In particular, the adhesive resin is preferably selected so as to have the resin composition as described below.

The adhesive resin included in the adhesive layer is not particularly limited, as long as it can bond the polyimide resin layer to an adherend (preferably, a heat-releasing metal plate). In particular, the adhesive resin preferably includes at least one siloxane-modified polyamideimide resin.

By including a siloxane-modified polyamideimide resin in the adhesive resin, adhesion with respect to the polyimide resin layer and heat resistance are further improved.

The siloxane-modified polyamideimide resin may be selected from known compounds. In particular, the siloxane-modified polyamideimide resin is preferably a siloxane-modified polyamideimide resin that is synthesized by using a siloxane-modified diamine. Examples of the siloxane-modified polyamideimide resin that is synthesized by using a siloxane-modified diamine include KS 9003, KS 9006 and KS 9900F, manufactured by Hitachi Chemical Co., Ltd.

The content of the adhesive resin (preferably, a siloxane-modified polyamideimide resin) in the adhesive layer is not particularly limited. From the viewpoint of adhesion and heat resistance, the content of the adhesive resin is preferably from 30% by mass to 60% by mass, more preferably from 40% by mass to 55% by mass, in a solid content of the adhesive layer. By including an adhesive resin in an amount of 30% by mass or more, adhesion of the adhesive layer with respect to the polyimide resin layer is further improved. When the adhesive resin is included in an amount of 60% by mass or less, heat resistance is further improved.

The adhesive layer preferably further includes at least one epoxy resin, in addition to a siloxane-modified polyamideimide resin. By including an epoxy resin, heat resistance tends to further improve.

The epoxy resin is not particularly limited and may be selected from commonly used epoxy resins. In particular, an epoxy resin that has two or more epoxy groups in one molecule and is compatible with a siloxane-modified polyamideimide resin is preferred, and an epoxy resin that has two to three epoxy groups in one molecule and is compatible with a siloxane-modified polyamideimide resin is more preferred.

In the specification, the term “compatible” refers to a property that the epoxy resin and the siloxane-modified polyamideimide resin can be uniformly mixed in terms of visual observation when the resins are mixed at a desired ratio.

The epoxy resin that is compatible with the siloxane-modified polyamideimide resin is preferably an epoxy resin having a similar structure to a structure of a diamine that constitutes the siloxane-modified polyamideimide resin, for example. Specifically, when the polyamideimide resin is composed of a phenylene diamine, an epoxy resin having a benzene ring is preferred. In consideration of heat resistance of the adhesive, a bisphenol epoxy resin is particularly preferred.

When the adhesive layer includes an epoxy resin, the adhesive layer preferably further includes a multifunctional resin having, in one molecule, three or more functional groups that can react with an epoxy group of the epoxy resin (hereinafter, also referred to as an “epoxy group-reactive resin”), more preferably further includes a multifunctional resin having, in one molecule, from 3 to 10 functional groups that can react with an epoxy group of the epoxy resin.

Examples of the resin having three or more functional groups that react with an epoxy group include multifunctional epoxy compounds having three or more epoxy groups, multifunctional phenolic compounds having three or more phenolic hydroxy groups, multifunctional amines having three or more amino groups, and urethane resins having three or more amino groups or hydroxy groups.

Examples of the multifunctional epoxy compounds having three or more epoxy groups include polyglycidyl ethers obtained by reacting epichlorohydrin with a polyhydric phenol such as bisphenol A, a novolac phenol resin or an orthocresol novolac phenol resin, or with a polyhydric alcohol such as 1,4-butanediol; polyglycidyl esters obtained by reacting epichlorohydrin with a polybasic acid such as phthalic acid or hexahydrophthalic acid; N-glycidyl derivatives of an amine, an amide or a compound having a heterocyclic nitrogen base; and alicyclic epoxy resins.

Examples of the multifunctional phenolic compounds include novolac phenol resins and resol phenol resins, which are a condensate of formaldehyde and at least one selected from the group consisting of hydroquinone, resorcinol, bisphenol A and halides thereof.

The content ratio of the epoxy group-reactive resin to the epoxy resin in the adhesive layer (epoxy group-reactive resin/epoxy resin) is not particularly limited. From the viewpoint of heat resistance and adhesion, the content ratio is preferably from 0.5 to 1.0, more preferably from 0.8 to 1.0.

The contents of the siloxane-modified polyamideimide resin, the epoxy resin and the epoxy group-reactive resin in the adhesive layer are not particularly limited. From the viewpoint of adhesion and heat resistance, preferably, the total amount of the resins in the solid content of the adhesive layer is 100% by mass or less, the content of the siloxane-modified polyamideimide resin is from 30% by mass to 60% by mass, the content of the epoxy resin is 10% by mass or more, and the content of the epoxy group-reactive resin is 10% by mass or more. More preferably, the content of the siloxane-modified polyamideimide resin is from 30% by mass to 60% by mass, the content of the epoxy resin is from 10% by mass to 30% by mass, and the content of the epoxy group-reactive resin is from 10% by mass to 30% by mass.

When the content of the epoxy resin is 10% by mass or more, compatibility of the siloxane-modified polyamideimide resin and the epoxy group-reactive resin is improved and heat resistance is further improved. When the content of the epoxy group-reactive resin is 10% by mass or more, heat resistance is further improved.

The ratio of the total content of the epoxy resin and the epoxy group-reactive resin to the content of the siloxane-modified polyamideimide resin in the adhesive layer (epoxy resin and epoxy group-reactive resin/siloxane-modified polyamideimide resin) is not particularly limited. From the viewpoint of adhesion and heat resistance, the ratio is preferably from 2/3 to 7/3, more preferably from 2/3 to 4/3.

The adhesive layer may further include a curing agent for the epoxy resin, a curing accelerator, and the like as needed. The curing agent for the epoxy resin and the curing accelerator are not particularly limited as long as these can react with the epoxy resin or accelerate curing. Examples of the curing agent and the curing accelerator include amine compounds, imidazole compounds, and acid anhydride compounds.

Examples of the amine compounds include dicyandiamide, diaminodiphenylmethane, and guanylurea. Examples of the acid anhydride compounds include phthalic anhydride, benzophenone tetracarboxylic dianhydride, and methylhimic acid. Examples of the curing accelerator include imidazole compounds such as alkyl group-substituted imidazole and benzoimidazole compounds.

The adhesive layer may also include an additive such as a silane coupling agent, an electrolytic corrosion resistance improver, a flame retardant or an anti-rust agent.

The method for providing the adhesive layer on the polyimide resin layer is not particularly limited as long as the adhesive layer can be formed so as to have a thickness of from 5 μm to 25 μm. For example, the adhesive layer can be formed by applying an adhesive varnish including an adhesive resin and a solvent on the polyimide resin layer, and drying the same. The method for applying the adhesive varnish is the same as the application method as described above, and the drying is the same as the drying process as described above.

The solvent residual rate in the adhesive layer after the drying process is not particularly limited, but preferably 2% by mass or less.

The substrate may further have a metal plate on the adhesive layer. The metal plate serves, for example, as a heat radiator. Examples of the kind of the metal plate include copper, aluminum, stainless steel, iron, and gold. From the viewpoint of adhesion, copper, aluminum or iron is preferred. From the viewpoint of heat-releasing properties, copper or aluminum is more preferred.

The size, thickness and the like of the metal plate are not particularly limited and may be selected in accordance with purposes.

<Method of Producing Substrate>

The method of producing the substrate of the invention includes: a process of preparing a polyimide precursor that is a reactant of an acid anhydride that includes a biphenyl tetracarboxylic acid anhydride and a diamine that includes a diaminodiphenyl ether and a phenylene diamine; a process of applying the polyimide precursor to a surface of a metal foil having an arithmetic average roughness (Ra) of 0.3 μm or less and a maximum roughness (Rmax) of 2.0 μm or less; a process of forming a polyimide resin layer by obtaining a polyimide resin from the polyimide precursor by causing cyclodehydration of the polyimide precursor in an atmosphere of a mixture of nitrogen gas and hydrogen gas; and a process of providing an adhesive layer on the polyimide resin layer.

In the process of preparing the polyimide precursor, the polyimide precursor may be prepared by reacting an acid anhydride with a diamine as described above, or may be prepared by selecting a commercially available polyimide precursor. Details of the process of applying the polyimide precursor, the process of forming the polyimide resin layer and the process of providing the adhesive layer are as described above.

<Heat-Releasing Substrate>

The heat-releasing substrate of the invention is the substrate of the invention in which the metal foil is circuit-processed. The method for circuit-processing to the metal foil on the substrate is not particularly limited, and may be selected from common methods for forming a circuit. For example, a circuit layer may be formed by a common photolithography method.

<Heat-Releasing Module>

The heat-releasing module of the invention includes the heat-releasing substrate as described above and an element disposed on the heat-releasing substrate. The element is mounted on the circuit layer of the heat-releasing substrate.

The element is not particularly limited, but is preferably an element that generates heat, more preferably a semiconductor element, further preferably an LED element.

The circuit layer on which an element is to be mounted can be formed by a common method of processing the metal foil of the substrate. The mounting of the element on the circuit layer may be performed by a common method without a particular limitation.

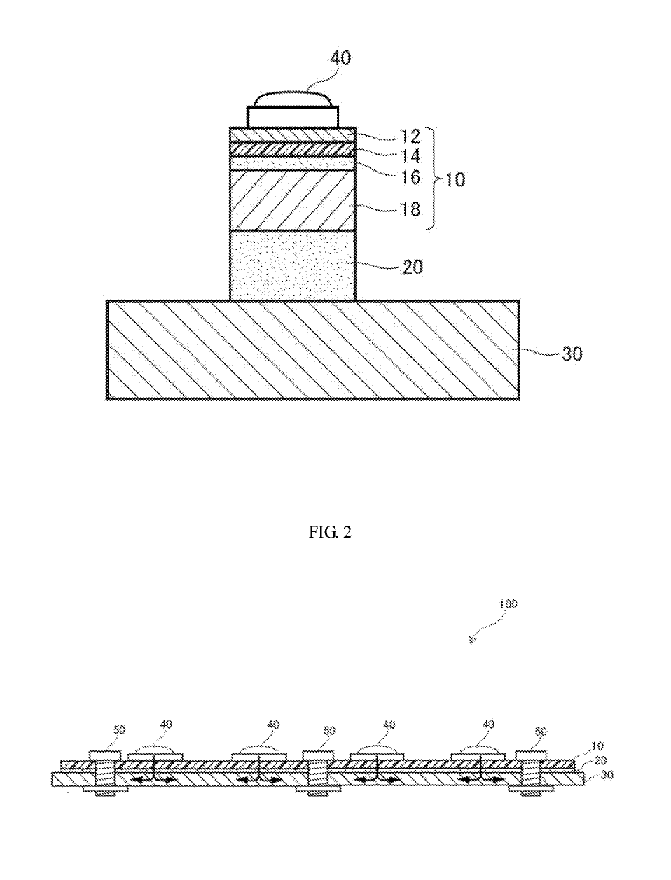

In the following, an example of an embodiment of the heat-releasing module is described with reference to the drawings. FIG. 1 is a schematic sectional view of an example of use of heat-releasing substrate 10 on which LED element 40 is mounted.

As shown in FIG. 1, heat-releasing substrate 10 has a structure in which metal plate 18, adhesive layer 16, polyimide resin layer 14 and circuit layer 12 are disposed in this order, and LED element 40 is mounted on circuit layer 12.

In FIG. 1, the heat-releasing module, which is heat-releasing substrate 10 on which LED element 40 is mounted, is used by disposing the same on metal exterior plate 30 via heat-conductive adhesive layer 20. The heat-conductive adhesive layer 20 may be electrically conductive. The heat generated from LED element 40 is conducted to metal plate 18 with high efficiency via circuit layer 12, polyimide resin layer 14 and adhesive layer 16 that constitute heat-releasing substrate 10, and conducted from metal plate 18 to metal exterior plate 30 via heat-conductive adhesive layer 20. Since heat-releasing substrate 10 has excellent heat conductivity and insulation properties, heat generated from LED element 40 can be released in a stable and efficient manner without deteriorating reliability even if heat-conductive adhesive layer 20 is electrically conductive.

FIG. 2 is a schematic sectional view of light-emitting module 100, which is an example of use of heat-releasing substrate 10 on which LED element 40 is mounted. As shown in FIG. 2, light-emitting module 100 has a structure in which metal exterior plate 30, heat-conductive adhesive layer 20 and heat-releasing substrate 10 on which LED elements 40 are mounted are disposed in this order. Further, heat-releasing substrate 10, heat-conductive adhesive layer 20 and metal exterior plate 30 are fixed with screws 50.

In light-emitting module 100, which includes heat-releasing substrate 10 and heat-conductive adhesive layer 20 having excellent heat conductivity, heat generated from LED elements 40 is conducted to metal exterior plate 30 with high efficiency via heat-releasing substrate 10 and heat-conductive adhesive layer 20 in directions shown by arrows, whereby a stable heat-releasing effect is exerted.

Further, in light-emitting module 100, heat-releasing substrate 10 exhibits a high breakdown voltage as a whole, whereby an excellent reliability is exerted.

### EXAMPLES

In the following, the invention is described more specifically with reference to the examples. However, the invention is not limited to these examples. Unless otherwise specified, “part” and “%” are based on mass.

<Preparation of Copper Foil with Polyimide Resin Layer>

(Synthesis of Polyimide Precursor)

In a 5 L reaction vessel made of glass attached with a thermocouple, an agitator and a nitrogen introduction port, 129.7 g (1.2 mol) of p-phenylene diamine (hereinafter, also referred to as PPD), 60.1 g (0.3 mol) of 4,4′-diaminodiphenyl ether (hereinafter, also referred to as DDE) and 3.6 kg of N-methyl-2-pyrrolidone (hereinafter, also referred to as NMP) were mixed while introducing nitrogen at approximately 300 ml/minute, thereby dissolving the diamine component. While cooling the solution with a water jacket to a temperature of 50° C. or lower, 441.3 g (1.49 mol) of 3,3′,4,4′-biphenyl tetracarboxylic acid anhydride (hereinafter, also referred to as BPDA) were gradually added and polymerization reaction was allowed to cause, thereby obtaining a polyimide precursor varnish.

The molar ratio of BPDA and the diamine component was 1:1.01.

(Process of Forming Polyimide Precursor Layer)

The polyimide precursor varnish obtained by the above process was applied onto a roughened surface of a copper foil with a comma coater to a thickness of 10 μm. As the copper foil, an electrolytic copper foil having a roughened surface on one side and a size of 540 mm in width and 35 μm in thickness (manufactured by Fukuda Metal Foil & Powder Co., Ltd.) was used.

The copper foil on which the polyimide precursor varnish had been applied was placed in a forced draft drying oven, and a solvent was removed from the polyimide precursor varnish. A polyimide precursor film with a copper foil, having a structure in which a polyimide precursor layer was formed on the copper foil, was thus prepared.

The residual solvent rate in the polyimide precursor layer was 35%.

The arithmetic average roughness (Ra) and the maximum roughness (Rmax) at the roughened surface of the electrolytic copper foil were 0.2 μm and 1.8 μm, respectively.

(Process of Forming Polyimide Resin Layer)

The polyimide precursor film with a copper foil obtained in the above process was subjected to a thermal treatment in a continuous manner in a circulating hot air oven, whereby a polyimide film with a copper foil was prepared as a result of cyclodehydration of the polyimide precursor.

The thermal treatment with a circulating hot air oven was performed by circulating a mixed gas of nitrogen by 99% by volume and hydrogen by 1% by volume, at a temperature of 400° C. for 10 minutes.

The thickness of the polyimide resin layer of the polyimide film with a copper foil was measured at randomly selected 10 points with a stylus profilometer, and the arithmetic average value was calculated as the average thickness of the polyimide resin layer. The average thickness was 3.0 μm.

(Preparation of Adhesive Varnish)

An adhesive varnish was prepared by weighing and mixing 55 parts of a siloxane-modified polyamideimide resin (trade name: KS9900F, manufactured by Hitachi Chemical Co., Ltd.), 30 parts of a bisphenol epoxy resin (trade name: EPICLON 840S, manufactured by DIC Corporation), 15 parts of a polyfunctional epoxy resin (trade name: EPPN502H, manufactured by Nippon Kayaku Co., Ltd.) and 0.45 parts of a curing accelerator (trade name: 2-ethyl-4-methyl imidazole, manufactured by Shikoku Chemicals Corporation).

### Example 1

### Process of Forming Adhesive Layer

The polyimide resin layer of the polyimide film with a copper foil obtained in the above process was subjected to a dry etching treatment with an oxygen plasma treatment at 500 W for 180 seconds, and the adhesive varnish obtained in the above process was applied on the polyimide resin layer with a comma coater such that the thickness after drying was 10 μm.

The drying was performed at 130° C. for 5 minutes. Substrate 1 (a polyimide film with a copper foil having an adhesive layer formed thereon) was thus prepared.

The residual solvent rate in the adhesive layer was 1% or less.

The substrate (a polyimide film with a copper foil having an adhesive layer formed thereon) was placed on an aluminum plate (manufactured by Nippon Light Metal Co., Ltd., A5052, no surface treatment, thickness: 1 mm) such that the adhesive layer was in contact with the aluminum plate. Then, a curing treatment was performed by hot plate pressing under conditions of 185° C., 3 MPa and 90 minutes. The evaluation sample A1 was thus obtained.

The following evaluation was performed with the obtained evaluation sample A1. The results are shown in Table 1.

(Heat Resistance)

A test piece was prepared by cutting the evaluation sample A1 into a 30-mm square and removing the copper foil by etching, such that a rectangular pattern of 10 mm 15 mm of the copper foil was formed. The test piece was dried at 120° C. for 30 minutes, and an evaluation sample was prepared by fixing a transistor (manufactured by NEC Corporation, D401A K35S) on the copper foil pattern with a solder ball.

A heat-conductive silicon resin was applied onto a base cooled at 0° C., and the evaluation sample A1 was placed thereon with the transistor side up. While measuring the temperature of the solder ball at the connection with a radiation thermometer (IT2-50, manufactured by Keyence Corporation), a power was applied by connecting a power source of 10V, 11V (manufactured by Metronix, B418A-16) and an earth cable. The heat resistance was calculated from the temperature and the value of the impressed current measured one minute after the application. The value of the impressed current was measured with a tester (manufactured by Hewlett-Packard Japan, Ltd., E2378A).

The target value of the heat resistance is 1.0° C./W or less.

(Breakdown Voltage)

A test piece was prepared by removing the copper foil of the evaluation sample A1 by etching, such that a round pattern having a diameter of 20 mm was formed. The test piece was dried at 120° C. for 30 minutes. Thereafter, the test piece was placed on a plate electrode of a withstand voltage tester (manufactured by Kikusui Electronics Corporation, TOS8700) with the aluminum plate side down, and an electrode having a diameter of 20 mm was placed on the round pattern. An alternating voltage of 2 mA and 0.5V was applied between the electrodes. Then, the voltage was gradually increased and a voltage at the conduction was determined as the breakdown voltage.

The target value of the breakdown voltage is 3.0 kV or more.

(Copper Foil Peel Strength)

A test piece was prepared by removing the copper foil of the evaluation sample A1 by etching, such that a line of 1 mm in width was formed. The test piece was dried at 120° C. for 30 minutes. The metal foil was peeled from the test piece before and after performing a thermal treatment at 150° C. for 500 hours, respectively, by fixing the aluminum plate of the test piece to a peel strength tester (manufactured by Orientec Co., Ltd., RTM500) at a peel angle of 90° and at a rate of 50 mm/minute, and the load for the peeling was measured.

The target value of the copper foil peel strength is 0.7 kN/m or more before performing a thermal treatment at 150° C. for 500 hours, and 0.5 kN/m or more after performing a thermal treatment at 150° C. for 500 hours.

(Interlayer Peel Strength)

A test piece was prepared by removing the copper foil and the polyimide resin layer of the evaluation sample A1 with a cutter, such that a line of 10 mm in width was formed on the copper foil. The test piece was dried at 120° C. for 30 minutes. The adhesive layer was peeled from the test piece before and after performing a thermal treatment at 150° C. for 500 hours, respectively, by fixing the aluminum plate of the test piece to a peel strength tester (manufactured by Orientec Co., Ltd., RTM500) at a peel angle of 90° and at a rate of 50 mm/minute, and the load for the peeling was measured.

The target value of the interlayer peel strength is 0.7 kN/m or more before performing a thermal treatment at 150° C. for 500 hours, and 0.5 kN/m or more after performing a thermal treatment at 150° C. for 500 hours.

(Solder Heat Resistance)

The evaluation sample A1 was cut into a 5-cm square, and half of the area of the copper foil was removed by etching. The test piece was dried at 120° C. for 30 minutes. Then, the test piece was floated in a solder bath at 300° C., and the time to cause expansion was measured by a float method.

The target value of the solder heat resistance is 60 seconds or more.

### Examples 2 to 6

The evaluation samples A2 to A6 were prepared in the same manner as Example 1, except that the thickness of the polyimide resin layer and the thickness of the adhesive layer were changed as shown in Table 1, and evaluation was performed in the same manner.

### Examples 7 and 8

The evaluation samples A7 and A8 were prepared in the same manner as Example 4, except that the arithmetic average roughness and the maximum roughness of the copper foil were changed as shown in Table 1, and evaluation was performed in the same manner.

### Comparative Examples 1 to 4

The evaluation samples C1 to C4 were prepared in the same manner as Example 1, except that the thickness of the polyimide resin layer and the thickness of the adhesive layer were changed as shown in Table 1, and evaluation was performed in the same manner.

### Comparative Examples 5 to 7

The evaluation samples C5 to C7 were prepared in the same manner as Example 2, except that the arithmetic average roughness and the maximum roughness of the copper foil were changed as shown in Table 1, and evaluation was performed in the same manner.

TABLE 1

| | | Example | | | | | | | | Comparative Example 1 | | | | | | |
|---|---|---|---|---|---|---|---|---|---|---|---|---|---|---|---|---|
| | Target Value | 1 | 2 | 3 | 4 | 5 | 6 | 7 | 8 | 1 | 2 | 3 | 4 | 5 | 6 | 7 |
| Copper foil arithmetic | — | 0.2 | 0.2 | 0.2 | 0.2 | 0.2 | 0.2 | 0.1 | 0.3 | 0.2 | 0.2 | 0.2 | 0.2 | 0.2 | 1.0 | 0.5 |
| average roughness (μm) | | | | | | | | | | | | | | | | |
| Copper foil roughened | — | 1.8 | 1.8 | 1.8 | 1.8 | 1.8 | 1.8 | 1.1 | 0.9 | 1.8 | 1.8 | 1.8 | 1.8 | 3.0 | 2.1 | 2.0 |
| maximum roughness (μm) | | | | | | | | | | | | | | | | |
| Resin layer thickness (μm) | — | 13 | 20 | 35 | 15 | 25 | 35 | 15 | 15 | 40 | 12 | 14 | 40 | 20 | 20 | 20 |
| Polyimide resin layer | — | 3 | 10 | 25 | 10 | 10 | 10 | 10 | 10 | 30 | 2 | 10 | 10 | 10 | 10 | 10 |
| average thickness (μm) | | | | | | | | | | | | | | | | |
| Adhesive layer | — | 10 | 10 | 10 | 5 | 15 | 25 | 5 | 5 | 10 | 10 | 4 | 30 | 10 | 10 | 10 |
| average thickness (μm) | | | | | | | | | | | | | | | | |
| Heat resistance (° C./W) | 1.0 or less | 0.6 | 0.7 | 0.9 | 0.6 | 0.8 | 0.9 | 0.8 | 0.8 | 1.3 | 0.5 | 0.6 | 1.2 | 0.8 | 0.7 | 0.7 |
| Breakdown voltage (kV) | 3.0 or more | 3.1 | 4.2 | 6.5 | 4.0 | 4.5 | 5.0 | 4.5 | 5.0 | 6.9 | 1.2 | 3.9 | 5.2 | 1.8 | 1.3 | 2.5 |
| Copper foil peel strength | 0.7 or more | 0.8 | 0.9 | 0.9 | 0.9 | 0.9 | 1.1 | 0.8 | 0.7 | 0.9 | 0.6 | 0.9 | 0.9 | 1.4 | 1.6 | 1.4 |
| before thermal treatment | | | | | | | | | | | | | | | | |
| (kN/m) | | | | | | | | | | | | | | | | |
| Copper foil peel strength | 0.5 or more | 0.7 | 0.8 | 0.8 | 0.8 | 0.8 | 1.0 | 0.8 | 0.7 | 0.8 | 0.4 | 0.8 | 0.8 | 1.0 | 1.4 | 1.4 |
| after thermal treatment | | | | | | | | | | | | | | | | |
| (kN/m) | | | | | | | | | | | | | | | | |
| Interlayer peel strength | 0.7 or more | 0.8 | 0.8 | 0.8 | 0.7 | 0.9 | 1.0 | 0.7 | 0.7 | 0.8 | 0.8 | 0.2 | 0.8 | 0.8 | 0.8 | 0.8 |
| before thermal treatment | | | | | | | | | | | | | | | | |
| (kN/m) | | | | | | | | | | | | | | | | |
| Interlayer peel strength | 0.5 or more | 0.6 | 0.6 | 0.7 | 0.6 | 0.8 | 0.8 | 0.6 | 0.5 | 0.7 | 0.6 | 0.1 | 0.6 | 0.6 | 0.6 | 0.6 |
| after thermal treatment | | | | | | | | | | | | | | | | |
| (kN/m) | | | | | | | | | | | | | | | | |
| Solder heat resistance | 60 or more | 300 | 300 | 300 | 300 | 300 | 300 | 300 | 300 | 300 | 300 | 15 | 300 | 300 | 300 | 300 |
| (seconds) | | | | | | | | | | | | | | | | |

The evaluation samples prepared by using substrates obtained in Examples 1 to 8 maintained the value of heat resistance of 1.0 (° C./W) or less while maintaining the breakdown voltage, solder heat resistance, copper foil and interlayer peel strength.

Comparative Examples 1 and 4 exhibited a large heat resistance. Comparative Example 2 was low in the breakdown voltage. Comparative Example 3 was low in the interlayer peel strength and the solder heat resistance. Comparative Examples 5 to 7 were low in the breakdown voltage.

The disclosure of Japanese Patent Application No. 2011-119555 is herein incorporated in this specification by reference. All publications, patent applications, and technical standards mentioned in this specification are herein incorporated by reference to the same extent as if each individual publication, patent application, or technical standard was specifically and individually indicated to be incorporated by reference.

1. A substrate, comprising:
a metal foil;
a polyimide resin layer having an average thickness of from 3 μm to 25 μm, the polyimide resin layer being disposed on a surface of the metal foil having an arithmetic average roughness (Ra) of 0.3 μm or less and a maximum roughness (Rmax) of 2.0 μm or less; and
an adhesive layer having an average thickness of from 5 μm to 25 the adhesive layer being disposed on the polyimide resin layer.

2. The substrate according to claim 1,
further comprising a metal plate that is disposed on the adhesive layer.

3. The substrate according to claim 1, wherein an adhesion between each of the layers after a thermal treatment at 150° C. for 500 hours is 0.5 kN/m or more, respectively.

4. The substrate according to claim 1, wherein a breakdown voltage of the polyimide resin layer and the adhesive layer as a whole is 3 kV or more.

5. The substrate according to claim 1, wherein an elastic modulus at normal temperature of an adhesive resin after curing, the adhesive resin being included in the adhesive layer, is from 200 MPa to 1,000 MPa.

6. The substrate according to claim 1, wherein the polyimide resin layer comprises a polyimide resin that is obtained from an acid anhydride that comprises a biphenyl tetracarboxylic acid anhydride and a diamine that comprises a diaminodiphenyl ether and a phenylene diamine.

7. The substrate according to claim 1, wherein the adhesive layer comprises a siloxane-modified polyamideimide resin and an epoxy resin.

8. The substrate according to claim 1, wherein:
a total content of a resin in a solid content of the adhesive layer is 100% by mass or less; and
contents in the solid content of a siloxane-modified polyamideimide resin, an epoxy resin having two or more epoxy groups in a molecule that is compatible with the siloxane-modified polyamideimide resin, and a polyfunctional resin having three or more functional groups that are reactive with the epoxy group in a molecule, which are included in the resin, are from 30% by mass to 60% by mass, 10% by mass or more and 10% by mass or more, respectively.

9. A heat-releasing substrate that is the substrate according to claim 1, wherein the metal foil is circuit-processed.

10. A heat-releasing module, comprising the heat-releasing substrate according to claim 9 and an element disposed on the heat-releasing substrate.

11. A method of producing a substrate, the method comprising:
a process of preparing a polyimide precursor that is a reactant of an acid anhydride that comprises a biphenyl tetracarboxylic acid anhydride and a diamine that comprises a diaminodiphenyl ether and a phenylene diamine;
a process of applying the polyimide precursor to a surface of a metal foil having an arithmetic average roughness (Ra) of 0.3 μm or less and a maximum roughness (Rmax) of 2.0 μm or less;
a process of forming a polyimide resin layer by obtaining a polyimide resin from the polyimide precursor by causing cyclodehydration of the polyimide precursor in an atmosphere of a mixture of nitrogen gas and hydrogen gas; and
a process of providing an adhesive layer on the polyimide resin layer.

12. The method of producing a substrate according to claim 11, wherein the polyimide precursor is a reactant obtained by reaction of a diamine that comprises from 0.15 mol to 0.25 mol of the diaminodiphenyl ether and from 0.75 mol to 0.85 mol of the phenylene diamine with 1 mol of the biphenyl tetracarboxylic acid anhydride.
